(19) United States
(12) Patent Application Publication
(10) Pub. No.: US 2008/0087939 A1
(43) Pub. Date: Apr. 17, 2008

(54) Nonvolatile semiconductor memory and manufacturing method for the same

(75) Inventor: Akiko Nara, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/987,729

(22) Filed: Dec. 4, 2007

Related U.S. Application Data
(63) Continuation of application No. 11/411,804, filed on Apr. 27, 2006, now abandoned.

(30) Foreign Application Priority Data
Apr. 28, 2005 (JP) 2005-133624

(51) Int. Cl. H01L 29/788

(52) U.S. Cl. 257/321; 257/E29.3

(57) ABSTRACT

A nonvolatile semiconductor memory device comprising: a gate electrode portion comprising: a floating gate electrode formed above a main surface of a semiconductor substrate of a first conductivity type, separated from the substrate by a tunnel insulating film; an inter-electrode insulating film formed on the floating gate electrode and formed of a stacked structure film of at least one type of high dielectric permittivity material; and a control gate electrode formed above the inter-electrode insulating film; and at least one interface layer between the inter-electrode insulating film and the floating gate electrode or the inter-electrode insulating film and the control gate electrode; source and drain regions of a second conductivity type which are formed on the main surface of the substrate with the gate electrode portion being arranged between the source and drain regions.

### CROSS-REFERENCE TO RELATED APPLICATIONS

This application is based upon and claims the benefit of priority from the prior Japanese Patent Application No. 2005-133624, filed on May 28, 2005, the entire contents of which are incorporated herein by reference.

### BACKGROUND OF THE INVENTION

1. Field of the Invention

This invention relates to a nonvolatile semiconductor memory device and a method of manufacturing the same. More particularly, this invention relates to a nonvolatile semiconductor memory device which improves an inter-electrode insulating film between a floating gate electrode and a control gate electrode in a stacked gate configuration where the floating and the control gate electrodes are stacked one on top of the other via the inter-electrode insulating film and to a method of manufacturing the nonvolatile semiconductor memory device.

2. Description of the Related Art

A MOS structure with a stacked gate configuration has been used for the memory cells in a NAND nonvolatile semiconductor memory device. The MOS structure with a stacked gate configuration is such that a floating gate electrode is formed above a semiconductor substrate via a tunnel insulating film and a control gate electrode is formed above the floating gate electrode via the inter-electrode insulating film (or an inter-poly insulating film). In this type of memory cell, to gain the electric capacitance ratio of the floating gate electrode to the control electrode an SiO₂/SiN/SiO₂ film (hereinafter, referred to as an ONO film) whose permittivity is higher than that of a silicon oxide film has been used as an inter-poly insulating film.

With the recent miniaturization of memory cells, the application of a material whose permittivity is higher than that of an ONO film as an inter-poly insulating film has been under examination. Of the high-dielectric films, an aluminum oxide (Al₂O) film particularly has a high thermal stability and therefore is less liable to react with poly-silicon. Therefore, an aluminum oxide film has good compatibility with the manufacturing process for NAND semiconductor elements and therefore is a premising film for an inter-poly insulating film in the near future.

However, when an aluminum oxide film is used as an inter-poly insulating film, the following problem arises: when a high electric field is applied to the inter-poly insulating film, the leakage level cannot be suppressed below the memory retaining characteristic.

### BRIEF SUMMARY OF THE INVENTION

According to a first aspect of the invention, there is provided a nonvolatile semiconductor memory device comprising: a nonvolatile semiconductor memory device comprising: a gate electrode portion comprising: a floating gate electrode formed above a main surface of a semiconductor substrate of a first conductivity type, separated from the substrate by a tunnel insulating film; an inter-electrode insulating film formed on the floating gate electrode and formed of a stacked structure film of at least one type of high dielectric permittivity material; and a control gate electrode formed above the inter-electrode insulating film; and at least one interface layer between the inter-electrode insulating film and the floating gate electrode or the inter-electrode insulating film and the control gate electrode; source and drain regions of a second conductivity type which are formed on the main surface of the substrate with the gate electrode portion being arranged between the source and drain regions.

### BRIEF DESCRIPTION OF THE SEVERAL VIEWS OF THE DRAWING

FIG. 1 is a cross-sectional view of the memory device according to the first embodiment.

FIG. 2 shows cross-sectional views of the non-volatile memory device at various steps of the manufacturing process according to the first embodiment.

FIG. 3 is a plot showing the relation between the dielectric constants of various insulator films and the tunneling barrier height.

FIG. 4 is a plot of the calculated leak current density as a function of the electric field strength for various insulator films.

FIGS. 5 and 6 are cross-sectional views of the memory device according to the second embodiment.

### DETAILED DESCRIPTION OF THE INVENTION

### First Embodiment

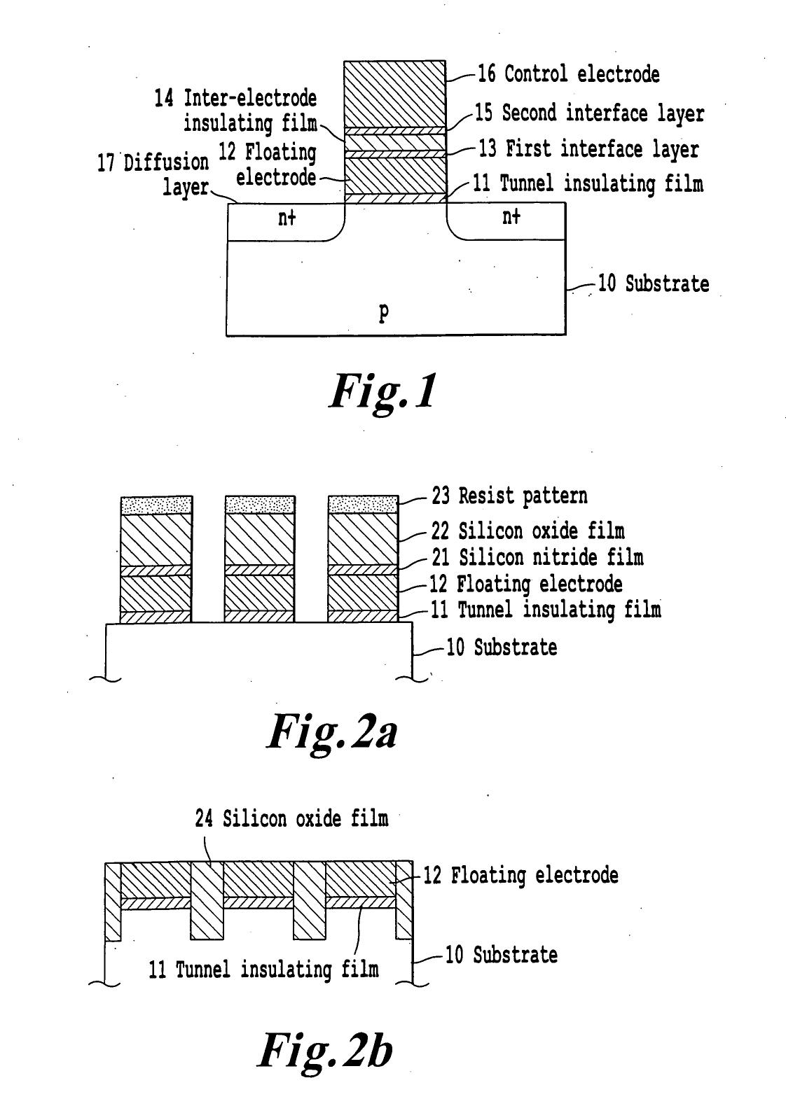

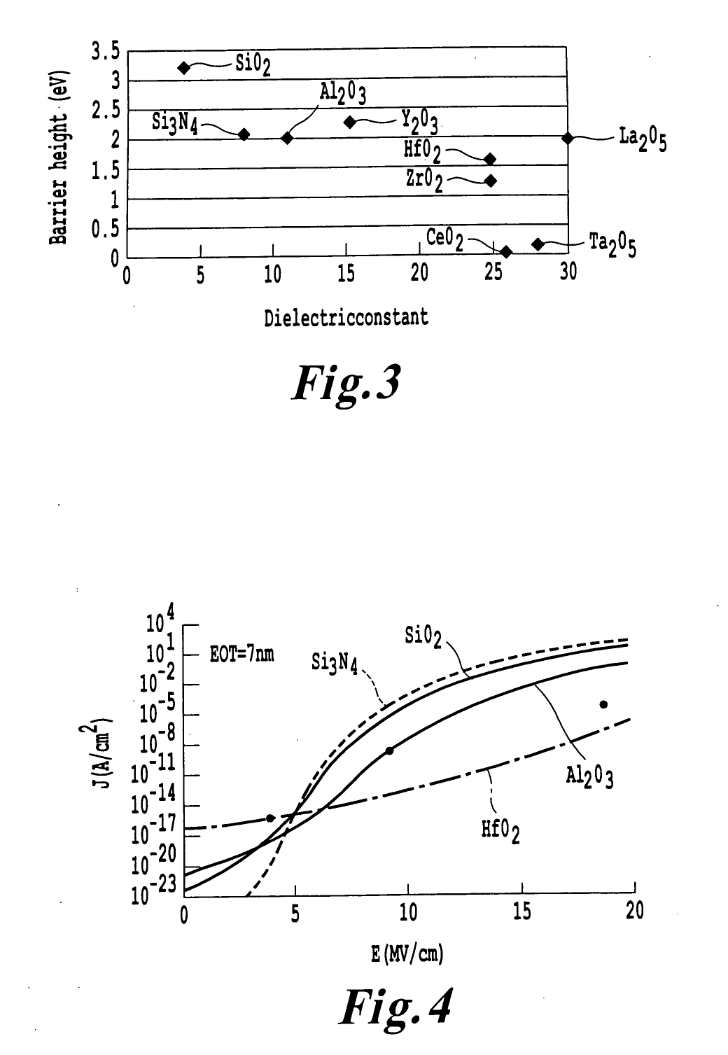

FIGS. 1 to 4 show the structure and manufacturing process of the non-volatile memory device according to a first embodiment. FIG. 1 shows the cross-section of the non-volatile semiconductor memory device according to the first embodiment.

On a p-type silicon substrate 10, a floating gate electrode 12, made of polysilicon, is formed on top of a tunnel insulator film 11, which is made by thermal oxidation- Then, above the floating gate electrode 12, a control gate electrode 16, made of polysilicon, is formed. The control gate 16 is separated from the floating gate 12 by an interpoly insulator layer 14, which is, for example, made of alumina (Al₂O₃). Additionally, an interface layer 13 may be inserted between the floating gate 12 and the interpoly layer 14. A second interface layer 15 may be inserted between the control gate 16 and the interpoly layer 14. The interface layers 13 and 15 can, for example, be made of aluminum metal. The thickness of each of the interface layers 13 and 15 is, for example 1 nm to 2 nm. The thickness of the interpoly layer 14 is, for example, 9 nm to 13 nm.

Although the first interface layer 13 and the second interface layer 15 are described in the first embodiment as consisting of aluminum metal, it is possible to use other compositions, which contain at least one of the following materials: gold (Au), platinum (Pt), cobalt (Co), beryllium (Be), nickel (Ni), rhodium (Rh), palladium (Pd), tellurium (Te), rhenium (Re), molybdenum (Mo), titanium nitride (TiN), tantalum nitride (TaN), tungsten nitride (WN), hafnium (Hf), titanium (Ti), tantalum (Ta), manganese (Mn), zinc (Zn), zirconium (zr), indium (In), lead (Pb), and bismuth (Bi) In the first embodiment, the interpoly layer 14 was described as consisting of alumina (Al₂O₃). The interpoly layer 14 can also be made of other materials, containing at least one of: hafnium oxide (HfO₂), lanthanum oxide (La₂O₃), yttrium oxide (Y₂O₃), cerium oxide (Ce₂0₃), titanium oxide (Ti₂O₃), zirconium oxide (ZrO₂), silicon dioxide (SiO₂), silicon nitride (Si₃N₄)

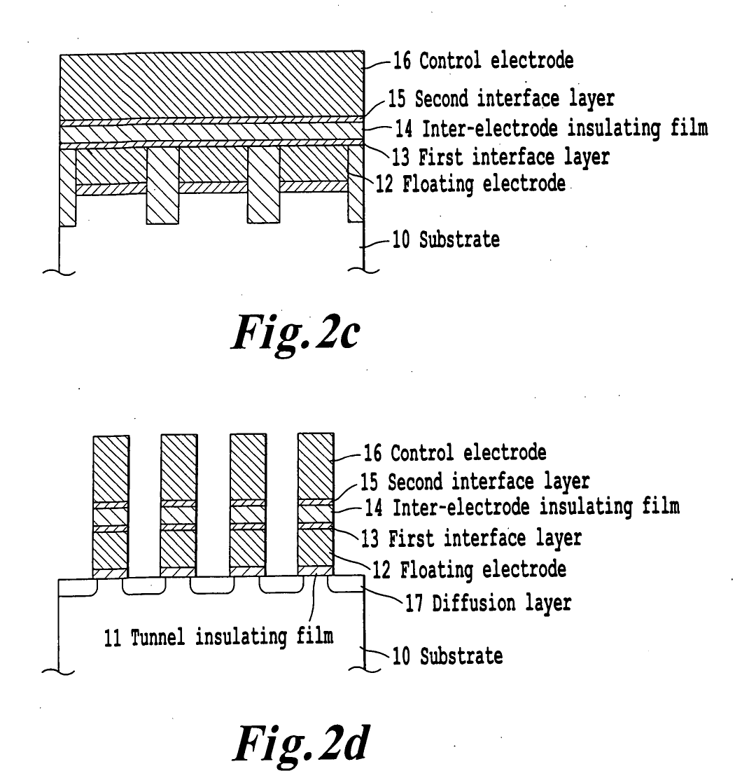

The manufacturing process according to the first embodiment is described using the cross-sectional device diagrams in FIG. 2. FIGS. 2A to 2C show cross-sections of the device along the length of the channel and FIG. 2D shows the cross-section of the device in the direction of channel width.

This figure assumes that the NAND cell is a part of an in-series connection of two or more memory cells.

First, as shown in FIG. 2A, the tunnel insulator film 11; the polysilicon film used as a floating gate electrode 12, the silicon nitride film 21, and the silicon dioxide film 22 are formed on a p-type silicon substrate 10. Next, a photoresist pattern 23 is formed on the device and layers 22, 21, 12, and 11 are etched in regions exposed by the resist pattern 23.

For example, the silicon substrate 10 is thermally oxidized to form a 7 nm to 8 nm-thick tunnel oxide layer 11. A 60 nm-thick polysilicon layer is deposited by CVD to form the floating gate electrode 12. Next a 150 nm-thick silicon nitride film 21 is deposited by LPCVD, followed by 150 nm-thick silicon dioxide layer 22, which is grown by LPCVD using TEOS gas and annealed. A photoresist pattern 23 is then formed on the surface of the silicon dioxide film 22.

Next, the silicon dioxide layer 22 is etched by reactive ion etching by using the photoresist pattern 23 as a mask. The silicon nitride layer 21 is then etched by reactive ion etching by using the etched silicon dioxide layer 22 as a mask. Next, the polysilicon layer 12, which will form the floating gate of the device, is etched by reactive ion etching by using the silicon nitride layer 21 as a mask. Finally, the tunnel oxide layer 11 is etched.

As shown in FIG. 2B, the substrate 10 is selectively etched by reactive ion etching, using the silicon nitride layer 21 as a mask and the etched holes are filled with silicon dioxide to form shallow trench isolation 24. The surface of the silicon dioxide film that was used to fill the shallow trench isolation holes 24 by CVD, is planarized by CMP up to the silicon nitride layer 21. The silicon nitride film 21 is then removed by wet etching.

Next, as shown in FIG. 2C and explained in detail later, the first interface layer 13 is formed. The interpoly insulator layer 14 is then grown on top of the first interface layer 13. Next, the second interface layer 15 is formed, followed by a polysilicon film 16 with a thickness of, for example, 200 nm, forming the control gate electrode. Subsequently, as shown in FIG. 2D, a word line pattern is formed by etching the polysilicon control gate electrode layer 16 and the floating gate electrode layer 12 by using a mask that is not shown in the figure. After that, phosphorous ion is implanted into substrate 10, for example, with an ion energy of 40 KeV and a dose of 2×10¹⁵ cm⁻², to form the source and drain regions 17 with high n+ type impurity concentration. This step completes the construction of a non-volatile NAND-type memory cell according to the first embodiment.

According to the first embodiment, as shown in FIG. 2C, the first interface layer 13, the interpoly insulator layer 14, and the second interface layer 15 are formed as follows. For example, the interface layers 13 and 15 may consist of aluminum metal and the interpoly layer 14 may consist of alumina (Al₂O₃) . Layers 13, 14, and 15 can be formed by CVD, where Al(CH₃)₃, tetramethyl aluminum (TMA) is used as a process gas. The substrate is loaded into the CVD chamber after forming the polysilicon floating gate. The process gases, TMA and hydrogen are introduced into the CVD chamber, forming aluminum metal on the polysilicon surface as a result of reduction of TMA. The thickness of the aluminum metal layer is controlled by adjusting the TMA and hydrogen gas ratio, gas flow rate, gas flow timing, substrate temperature, etc. According to the first embodiment, the thickness of the first interface layer 13 is between 1 nm and 2 nm.

Next, an alumina layer is grown to form the interpoly insulator layer 14. In the first embodiment, TMA is used as the process gas. After finishing the growth of the first interface layer 13, the gas supplies are stopped and the process chamber is evacuated. The chamber is then filled with oxygen gas, ozone (O₃), or water (H₂O), followed by the introduction of TMA gas.

By this method it is possible to vary continuously the oxidation of aluminum, from a conducting metal to an insulating oxide, by using the same source gas and growth method. In the first embodiment, the second interface layer 15 consists of aluminum metal and can thus be formed by the same CVD technique. The second interface layer 15 is formed on top of the interpoly layer 14 by stopping the gas flow after the growth of the interpoly insulator layer 14, evacuating the process chamber, and introducing the TMA process gas together with hydrogen into the chamber. In the first embodiment, the thickness of the second interface layer 15 is between 1 nm and 2 nm.

In the first embodiment, the leakage current of the alumina interpoly layer between the floating gate 12 and the control gate 16 is reduced by several orders of magnitude by the introduction of the metallic aluminum first and second interface layers 13 and 15.

Although according to the first embodiment, the first and second interface layers, 13 and 15, are made of metallic aluminum, other interface materials can be used as well, containing at least one of the following: gold (Au), platinum (Pt), cobalt (Co), beryllium (Be), nickel (Ni), rhodium (Rh), palladium (Pd), tellurium (Te), rhenium (Re), molybdenum (Mo), titanium nitride (TiN), tantalum nitride (TaN), tungsten nitride (WN), hafnium(Hf), titanium (Ti), tantalum (Ta), manganese (Mn), zinc (Zn), zirconium (Zr), indium (In), lead (Pb), and bismuth (Bi).

The first interface layer 13 and the second interface layer 15 can be made of the same materials or different materials. The reasons why inserting the first interface layer 13 between the floating gate 12 and the interpoly insulator layer 14 and the second interface layer 15 between the control gate 16 and the interpoly layer 14 reduces the leakage current in the interpoly insulator layer 14, are given here. First, the materials used to form the first interface layer 13 and the second interface layer 15 have a higher work function than polysilicon, which is used to form the floating gate electrode 12 and the control gate electrode 16. For example, the work function of aluminum (Al) is about 4.3 eV, which is larger than the work function (about 3.9 eV) of n+ type polysilicon that is used to form the floating gate electrode 12 and the control gate electrode 16.

By having interface layers with larger work functions than polysilicon, the leakage current flowing from gate electrodes into the insulator layer is effectively reduced by several orders of magnitude. During writing and erasing operations, it is thus possible to maintain the same level of FN tunnel current in the tunnel oxide layer 11, while at the same time reducing the leak current between the floating gate electrode 12 and the control gate electrode 16. The advantage of the reduced leak current between the floating gate electrode 12 and the control gate electrode 16 is increased retention of the memory cell and higher reliability.

other materials than aluminum can be used to form the first insulator layer 13 and the second insulator layer 15, as long the selected material has a higher work function than n+ type polysilicon. The work functions of possible interface layer materials are: 5.3 eV for platinum (Pt), 5.1 ev for gold (Au), nickel (Ni), and palladium (Pd), 5.0 eV for cobalt (Co), beryllium (Be), rhenium (Re), and rhodium (Rh), 4.9 eV for Tellurium, 4.6 ev for molybdenum (Mo), 4.3 eV for zinc (Zn) and lead (Pb), 4.2 eV for indium (In) and bismuth (Bi), 4.1 eV for titanium (Ti) , zirconium (Zr), and manganese (Mn), 4.0 eV for hafnium (Hf). All of these work functions are larger than the 3.9 eV work function of n+ type polysilicon and thus these materials can be used to reduce leak currents between the polysilicon electrodes 12 and 16, and the interpoly insulator layer 14. Furthermore, gold (Au), platinum (Pt), cobalt (Co), beryllium (Be), nickel (Ni), rhodium (Rh), palladium (Pd), tellurium (Te), and rhenium (Re) have work functions that are larger than the 4.8 eV work function of p+ type polysilicon. These materials can be used to reduce leakage current in the interpoly layer 14 even when p+ type polysilicon is used to form the floating gate electrode 12 or the control gate electrode 16.

Moreover, by forming the first interface layer 13 and the second interface layer 15, it is possible to avoid direct contact between the polysilicon electrodes 12 and 16, and the high dielectric constant oxide insulator interpoly layer, thus reducing the formation of silicates at the top of the polysilicon floating gate 12 and the bottom of the polysilicon control gate 16. Silicates are undesirable in the interpoly region between the floating gate 12 and the control gate 16 because silicates have a lower dielectric constant than the interpoly insulator material and the presence of silicate layers on the polysilicon electrode surfaces would reduce the capacitance of the capacitor formed by the floating gate electrode 12 and the control gate electrode 16.

Nitrides, such as titanium nitride (TiN), tantalum nitride (TaN), and tungsten nitride (WN), have the additional advantages of reduced oxygen permeability and smaller fixed charge at the interfaces.

Gold (Au), platinum (Pt), and molybdenum (Mo) have good adhesion to the high dielectric constant film, and, moreover, the reactivity of these elements with the high dielectric constant film is low.

Tungsten (W), titanium nitride (TiN), tantalum nitride (TaN), and tungsten nitride (WN) have good compatibility with general dry processing methods.

Although the first interface layer 13 and the second interface layer 15 may form silicides at the interfaces with the polysilicon floating gate 12 and the polysilicon control gate 16, these silicides are electrically conducting and thus function electrically as parts of the polysilicon floating and control gate electrodes 12 and 16.

Thus, it is possible to reduce leakage current between the floating and control gate electrodes in a stacked-gate non-volatile semiconductor memory cell, by inserting an electrically conducting material at the interfaces between the polysilicon gate electrodes and the high dielectric constant interpoly insulator film. The interface layers are effective at reducing leakage current in the gate stack not only under high field conditions, but also at low applied fields, which is normally difficult to achieve with high dielectric constant insulator films.

In the first embodiment, alumina was used to form the interpoly insulator layer. Other materials can also be used in the place of alumina, containing at least one of the following materials: hafnium oxide (HfO₂), lanthanum oxide (La₂O₃), yttrium oxide (Y₂O₃), cerium oxide (Ce₂O₃), titanium oxide (Ti₂O₃), zirconium oxide (ZrO₂), silicon dioxide (SiO₂), and silicon nitride (Si₃N₄).

Generally, the level of leakage current flowing in a dielectric film at a particular electric field depends on the height of the energy barrier that electrons need to overcome when moving from an electrode into the insulator layer. A phenomenological relationship exists between the barrier height and the dielectric permittivity of the insulator material, with higher permittivity materials generally having a lower barrier height.

As shown in FIG. 1, silicon dioxide (SiO₂) has a permittivity of 3.9 and a barrier height of 3.2 eV. In comparison, silicon nitride (Si₃N₄) has a permittivity of 8 and a barrier height of 2.1 eV, aluminum oxide (Al₂O₃) has a permittivity of 9 to 11 and a barrier height of 2.0 eV to 2.5 eV, hafnium oxide (HfO₂) has a permittivity of 20 to 25 and a barrier height of 1.0 eV to 1.5 eV, and tantalum oxide (Ta₂O₅) has a permittivity of 28 and a barrier height of 0.2 to 1.0 eV.

Although not shown, it has been reported that a yttrium oxide Y₂O₃) has a permittivity of 15 and a barrier height of 2.3 eV, zirconium oxide (ZrO₂) has a permittivity of 25 and a barrier height of 1.4 eV, titanium oxide (TiO₂) has a permittivity of 80 to 180 and a barrier height of 0.2 to 1.0 eV, and lanthanum oxide (La₂O₅) has a permittivity of 30 and a barrier height of 2.3 eV.

The capacitance of a parallel-plate capacitor, such as the floating gate—interpoly insulator—control gate stack, is proportional to the permittivity Of the insulator material and inversely proportional to the thickness of the insulator layer. By using an insulator material with a higher permittivity, it is thus possible to build a device with a larger physical insulator film thickness while maintaining the same device capacitance, or oxide equivalent thickness. The increased physical thickness of a device leads to a reduction of the leak current. On the other hand if the permittivity is high, the barrier height decreases. A smaller barrier height increases the probability of tunneling for electrons above the Fermi level and the chance that an electron may go over the barrier and flow from an electrode into the insulator layer. A lower barrier height thus increases the leakage current density of a device. That is, the leakage current flowing through an interpoly insulator film is determined by two competing mechanisms of decreasing the leakage current by increasing the permittivity of the insulator and increasing the tunneling leak current by lowering the barrier height.

The leakage currents flowing in devices based on the materials listed above were estimated by summing the contributions of direct tunneling current and Fowler Nordheim (FN) tunneling current, which was calculated using the WKB approximation. A comparison of the calculation results for Al₂O₃, HfO₂, Si₃N₄, and SiO₂, all of which can be used as interpoly insulator materials, are shown in FIG. 4.

In the calculation, it was assumed that the oxide equivalent film thickness is 7 nm, the effective mass is 0.46 mₑ, and the temperature is 85° C.

When a high-permittivity film is used as an interpoly insulating layer, a very high electric field is applied during the writing operation of the memory element. When a high electric field is applied, leakage current flowing in the interpoly insulating layer has to be suppressed to one-tenth or less of the leakage current flowing in the tunnel insulator film. For example, when the film thickness of the tunnel insulator film is 7.5 nm, and the coupling ratio of the runnel insulator film to the interpoly insulator film is 0.58, the electric field applied to the interpoly insulator film can be as high as 18 MV/cm. The allowed leakage current in the interpoly insulator film during writing is about 1×10⁻⁶ A/cm².

To achieve acceptable memory retention characteristics, it is essential to suppress interpoly insulator leakage currents that would otherwise allow the charge stored in the floating gate to be lost due to leakage from the floating gate to the control gate. For example, under the same device conditions as described above, when the electric field applied to the interpoly insulating film is 4 MV/cm, the leakage level of the interpoly insulating film is required to be equal to or less than 1×10⁻¹⁶ A/cm². When the element is erased, a negative high electric field (−16 MV/cm) is applied. At this time, it is necessary to suppress the leakage current flowing in the interpoly insulating film to 1×10⁻⁶ A/cm² or less.

As described above, it is essential to decrease the leakage current in the interpoly insulator film used in a nonvolatile semiconductor memory device not only under high positive and negative electric fields but also at low electric fields. Similarly, in the tunnel insulator film, it is essential to decrease the leakage current not only under positive and negative high electric field conditions but also in the presence of low electric fields. Although the calculation results suggest that when a hafnium oxide film is used as an interpoly insulating film, the leakage current can be suppressed below the leakage levels required for the write operation and the leak current remains sufficiently small even under low electric fields, for example at 4 MV/cm, the calculated leakage current is very close to the minimum requirements that would still result in a device with adequate performance characteristics, measurements of devices that contain only a hafnium oxide film as an interpoly insulator showed that the actual leakage current exceeds the calculated value by several orders of magnitude. The reason for this is the presence of additional leak current paths that are related to defects and add to the tunnel leakage currents obtained from the calculations. Moreover, it is conceivable that crystallization progresses as a result of heat treatments after the insulator film formation. The growth of crystalline grains in the film increases the film surface roughness, permitting the leakage current to increase due to the concentration of the electric field at the grain boundaries. For this reason, it is impossible to use only a hafnium oxide film as an interpoly insulator film. The examination made by the inventors showed that the use of high-work function interface layers in the memory structure suppressed the surface roughness of the films after heat treatment and prevented crystallization from occurring in the insulator layer, although a drop of the interpoly leak current density to the value estimated in the theoretical calculations was not achieved.

### Second Embodiment

While in the first embodiment, the interpoly insulator film was formed by CVD, interpoly insulator films may be formed by sputtering in a similar manner. The structure of the device according to the second embodiment is identical to the structure described in the first embodiment and the device structure description is therefore omitted here.

In the second embodiment of the present invention, the structure of the device is identical to the device described in the first embodiment, except for the formation of the first interface layer 13, the interpoly insulator layer 14 and the second interface layer 15, shown in FIG. 2C. The details of the film formation process according to the second embodiment are presented here. According to the second embodiment, the first interface layer 13, the interpoly insulator layer 14, and the second interface layer 15 are formed by the sputtering method.

The substrate is loaded into the sputtering chamber after the formation of the polysilicon floating gate electrode and the substrate temperature is adjusted with a radiative lamp heater. The sputtering target is positioned in front of the substrate at an angle of 45 degrees to the substrate surface.

For example, when using hafnium as a material for the first interface layer 13, a hafnium metal target is used in the sputtering system, and a metallic hafnium film is grown on the polysilicon surface by plasma sputtering.

In the case of the second embodiment, for example, the first interface layer made of hafnium has a thickness of 1 to 2 nm. It is possible to control the process gas atmosphere and, for example, nitrogen gas can be admitted into the sputtering chamber during film growth to obtain a nitride film.

Next, a hafnium oxide film is grown on top of the first interface layer 13 by the same sputtering method, forming the interpoly insulator layer 14. In addition, although this example showed the use of a hafnium oxide film, it is possible to use several sputtering targets at the same time. For example, co-sputtering from a hafnium metal target and an aluminum metal target in an oxidizing gas environment can be used to grow a hafnium aluminate (HfAlOₓ) film. Insulating oxide films can be grown from individual metal targets, metal alloy targets, oxide targets, or any combination of targets in an oxidizing atmosphere.

Moreover, the composition of the insulator layer can be graded or several layers with different compositions can be grown, by varying the gas atmosphere during the insulator film growth. The capability of changing the film composition by controlling the process gas flow and sputter timing can be used to grow three or more individual layers or a single layer with continuous composition gradients.

Although it is advantageous to grow the first interface layer 13, the interpoly insulator layer 14, and the second interface layer 15 continuously in a single process, it is feasible to grow each layer separately, possibly by different film growth techniques. For example, the first interface layer 13 can be grown by sputtering, the interpoly insulator layer 14 can be grown by CVD, and the second interface layer 15 can again be grown by sputtering.

Furthermore, in addition to sputtering and CVD, other film growth techniques can also be used, such as vacuum evaporation, laser ablation, and MBE or any combination of these techniques.

The choice of materials is not limited to hafnium and aluminum, as discussed in the previous example. Other materials, such as yttrium oxide, zirconium oxide, tantalum oxide, titanium oxide, or lanthanum oxide can also be used to form the interpoly and tunnel insulator layers. Furthermore, it is possible to use a multilayer structure to form the interpoly insulator, consisting of oxide layers and silicon dioxide or silicon nitride layers.

The reduction of leak current according to the second embodiment is functionally equivalent to the first embodiment.

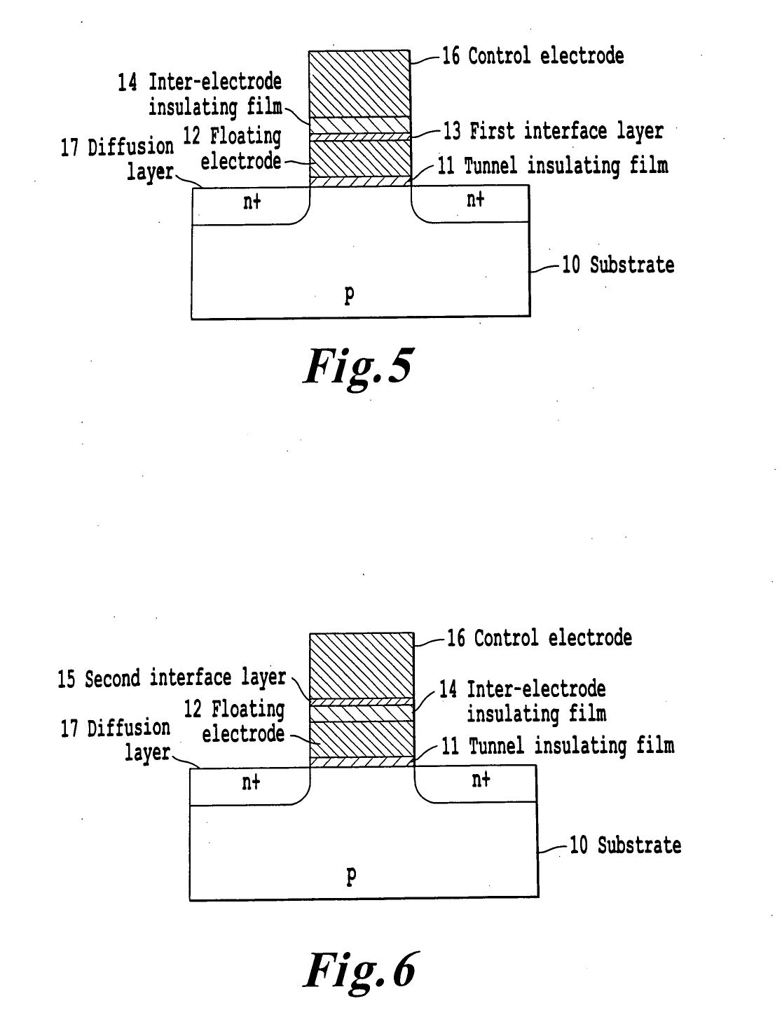

Moreover, the following modifications of the device structure can be considered. As shown in FIG. 5, the first interface layer 13 is formed between the floating gate electrode 12 and the interpoly insulator layer 14. The control gate electrode 16 can be formed directly on top of the interpoly insulator layer 14, omitting the second interface layer. Another variation of the device structure is shown in FIG. 6. In this case the interpoly insulator layer 14 is grown directly on top of the floating gate electrode 12 without an additional interface layer. The second interface layer 15 is grown on top of the interpoly insulator layer 14 before the formation of the control gate electrode 16.

The reduction of interpoly leakage current in the structures shown in FIGS. 5 and 6, where either the first interface layer 13 or the second interface layer 15 is omitted, depends on the polarity of the electric field that is applied to the control gate electrode 16. For example, the structure shown in FIG. 5 reduces the leakage of electrons from the floating gate electrode 12 to the control gate when the control gate electrode 16 when the control gate electrode is at a high positive bias. The structure shown in FIG. 6 behaves in an opposite manner, preventing the leakage of electrons from the control gate electrode 16 to the floating gate electrode 12 when the control gate electrode 16 is at a high negative bias.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising: a gate electrode portion comprising:
a floating gate electrode formed above a main surface of a semiconductor substrate of a first conductivity type, separated from the substrate by a tunnel insulating film;
an inter-electrode insulating film formed on the floating gate electrode and formed of a stacked structure film of at least one type of high dielectric permittivity material; and
a control gate electrode formed above the inter-electrode insulating film; and
at least one interface layer between the inter-electrode insulating film and the floating gate electrode or the inter-electrode insulating film and the control gate electrode;
source and drain regions of a second conductivity type which are formed on the main surface of the substrate with the gate electrode portion being arranged between the source and drain regions.

2. The nonvolatile semiconductor memory device according to claim 1, wherein the interface layer has a larger work function than the floating gate or control gate materials.

3. The nonvolatile semiconductor memory device according to claim 2, wherein the interface layer consist of at least one of the material from among Au, Pt, Co, Be, Ni, Rh, Pd, Te, Re, Mo, TiN, TaN, WN, Al, Hf, Ti, Ta, Mn, Zn, Zr, In, Pb, Bi.

4. The nonvolatile semiconductor memory device according to claim 1 wherein the inter-electrode insulating film consists of at least one of the materials from among Al₂O₃, HfO₂, La₂O₃, Y₂O₃, Ce₂O₃, Ti₂O₃, ZrO₂, SiO₂, Si₃N₄.

5. The nonvolatile semiconductor memory device according to claim 2 wherein the interface layer between the inter-electrode insulating film the floating gate electrode and the interface layer between the inter-electrode insulating film and the control gate electrode are made of the same material.

6. The nonvolatile semiconductor memory device according to claim 1 wherein the thickness of one of the interface layers is less than 2 nm.
